(19) United States
(12) Patent Application Publication
(10) Pub. No.: US 2020/0033000 A1
(43) Pub. Date: Jan. 30, 2020

(54) METHOD AND APPARATUS FOR EXHAUST GAS ABATEMENT UNDER REDUCED PRESSURE

(71) Applicant: Kanken Techno Co., Ltd., Nagaokakyo-shi, Kyoto (JP)

(72) Inventors: Michihiko YANAGISAWA, Nagaokakyo-shi, Kyoto (JP); Tsutomu TSUKADA, Nagaokakyo-shi, Kyoto (JP); Hiroshi IMAMURA, Nagaokakyo-shi, Kyoto (JP)

(21) Appl. No.: 16/603,410

(22) PCT Filed: Apr. 10, 2018
(86) PCT No.: PCT/JP2018/015035

§ 371 Date: Oct. 7, 2019

(30) Foreign Application Priority Data
May 29, 2017 (JP) 2017-105708

(51) Int. Cl. F23G 7/06; B01D 53/76; B01D 53/68; C23C 16/30; C23C 16/44

(52) U.S. Cl. CPC F23G 7/065; B01D 53/76; B01D 2257/204; C23C 16/308; C23C 16/4412; B01D 53/68

(57) ABSTRACT

The present invention provides an energy-efficient method and apparatus that can achieve exhaust gas abatement with a minimum use of diluent nitrogen gas. More specifically, the present invention is directed to a method and apparatus for exhaust gas abatement under reduced pressure, in which an exhaust gas supplied from an exhaust gas source through a vacuum pump is decomposed by combustion heat of a flame under a reduced pressure.

### TECHNICAL FIELD

The present invention relates to an exhaust gas abatement method and apparatus suitable for treatment of harmful gases such as combustible gases, toxic gases, and greenhouse gases emitted in the manufacturing processes mainly in the electronics industry.

### BACKGROUND ART

In the electronics industry for manufacturing semiconductors, liquid crystals, etc., various CVD processes are used for producing various films such as silicon nitride films, silicon oxide films, silicon oxynitride films, TEOS oxide films, high dielectric constant films, low dielectric constant films, and metal films.

Among these, for example, silicon-based thin films are formed by a CVD method mainly using an explosive and toxic silane-based gas. In this CVD method, after being used in a CVD process, a process gas containing the above-mentioned silane-based gas is discharged as an exhaust gas and rendered harmless in an abatement apparatus as described in Patent Literature 1 below. It is conventional practice to dilute the silane-based gas in the exhaust gas with a large amount of diluent nitrogen gas introduced upstream of the abatement apparatus so as to reduce the concentration of the silane-based gas to a level lower than the lower explosive limit.

Here, in a typical CVD process for forming silicon oxynitride films, SiH₄/NH₃/N₂O=1 slm/10 slm/10 slm (slm: standard liter per minute, i.e., a unit of flow rate of a gas at 0° C. and 1 atm expressed in terms of liters per minute) is used. Since the explosion range of SiH₄ is 1.3% to 100%, the gas mixture emitted in this CVD process must be diluted with about 76 parts of diluent nitrogen gas immediately after the emission. After the dilution, a conventional pyrolysis (thermal decomposition) apparatus, for example, a combustion type pyrolysis apparatus shown in Patent Literature 1 below or an atmospheric plasma type pyrolysis apparatus can be used to perform abatement treatment safely and reliably.

### CITATION LIST

### Patent Literature

[PTL 1] Japanese Laid-Open Patent Publication No. 11-333247

### SUMMARY OF INVENTION

### Technical Problem

However, the above-described conventional technique has a problem.

Specifically, the energy required for heating the exhaust gas mixture containing a silane-based gas and nitrogen gas used to dilute the silane-based gas as described above to the decomposition temperature is about 76 times the energy required for heating only the exhaust gas containing the undiluted silane-based gas. This means that in the conventional abatement process that requires dilution with nitrogen gas, not only the exhaust gas but also the nitrogen gas that is not directly involved in the abatement of the exhaust gas must be heated and thus the energy efficiency decreases, resulting in an increase in the cost of electricity, fuels, etc., in addition to an increase in the cost of nitrogen gas used in large amounts.

It is therefore a primary object of the present invention to provide an energy-efficient and economically efficient method and apparatus that can achieve exhaust gas abatement with a minimum use of diluent nitrogen gas without sacrificing safety.

### Solution to Problem

In order to achieve the above object, according to the present invention, exhaust gas abatement is performed under a reduced pressure.

A first aspect of the present invention is a method for exhaust gas abatement under reduced pressure, including decomposing an exhaust gas E that is supplied from an exhaust gas source 12 through a vacuum pump 14 by combustion heat of a flame 22 under a reduced pressure.

The first aspect of the present invention has, for example, the following advantageous effects.

The exhaust gas E supplied from the exhaust gas source 12 through the vacuum pump 14 is subjected to decomposition treatment using combustion heat of the flame 22 under a reduced pressure, which eliminates the need for using diluent nitrogen gas or reduces the use of the nitrogen gas to a minimum.

Since there is no need to dilute with diluent nitrogen gas or the use of the nitrogen gas can be reduced to a minimum, almost all combustion heat of the flame 22 can be used directly for decomposition of the exhaust gas E. In addition, since a region located downstream of the outlet of the exhaust gas E source and including the abatement treatment unit is under reduced pressure, even if the exhaust gas E contains toxic substances to humans, there is no risk that the exhaust gas E leaks from the system before being heated and decomposed by the combustion heat of the flame 22.

Furthermore, the use of the flame 22 as the heat source for heating decomposition treatment is advantageous. For example, since the accomplishments and experiences that have been made in the field of atmospheric-pressure combustion type exhaust gas abatement apparatuses, one of the currently dominating types of exhaust gas abatement apparatuses, can be used without any change, many of the existing facilities such as auxiliary pipes of such an atmospheric-pressure combustion type exhaust gas abatement apparatus can also be used without any change. In addition, power consumption can be reduced to reduce running costs.

Here, in the first aspect of the present invention, the reduced pressure is preferably in a range of 1 Torr or more and 400 Torr or less, and more preferably in a range of 100±50 Torr.

When the reduced pressure is lower than 1 Torr, an expensive and elaborate system is needed to achieve a high vacuum environment. In contrast, when the reduced pressure is higher than 400 Torr, which is not very different from the atmospheric pressure, the exhaust gas E must be diluted with a large amount of nitrogen gas.

A second aspect of the present invention is an apparatus for performing the method for exhaust gas abatement under reduced pressure described above. This apparatus 10 for exhaust gas abatement under reduced pressure is configured as follows, for example, as shown in FIG. 1 to FIG. 3.

Specifically, the apparatus 10 for exhaust gas abatement under reduced pressure according to the present invention includes: a reaction chamber 18 in which an exhaust gas E supplied from an exhaust gas source 12 through a vacuum pump 14 is decomposed by combustion heat of a flame 22; a combustion chamber 20 that is maintained at approximately atmospheric pressure and from which the flame 22 is emitted into the reaction chamber 18; and a downstream vacuum pump 24 that reduces a pressure in a region located downstream of an outlet of the vacuum pump 14 and including the reaction chamber 18.

Since the gas pressure is low in the reaction chamber 18 under the reduced pressure, it is difficult to burn a fuel to obtain the flame 22. In order to solve this problem, in the present invention, the fuel is burned in the combustion chamber 20 that is maintained at approximately atmospheric pressure to produce the flame 22, which is emitted into the reaction chamber 18, and thus the exhaust gas E can be decomposed under the reduced pressure using the combustion heat of the flame 22.

Preferably, the apparatus according to the second aspect of the present invention further includes a decomposition/reaction agent supply unit 26 that supplies at least one selected from the group consisting of water, air, O₂, H₂, and hydrocarbon gases, as a decomposition/reaction agent, to the reaction chamber 18.

In this case, even if the exhaust gas E mainly contains a large amount of combustible and harmful substances such as SiH₄ and NF₃, the addition of the decomposition/reaction agent allows these substances to be easily decomposed into stable substances or to be rendered harmless by reaction.

Preferably, the apparatus according to the second aspect of the present invention further includes a flame stabilizing nozzle 28 that is provided at a flame outlet 20b of the combustion chamber 20 to stabilize the flame 22.

In this case, it is possible to prevent the flame 22 from being extinguished by the flow of the exhaust gas E in the reaction chamber 18 so as to perform the decomposition treatment of the exhaust gas E by the combustion heat of the flame 22 more stably.

### Advantageous Effects of the Invention

According to the present invention, it is possible to provide an energy-efficient and economically efficient method and apparatus that can achieve exhaust gas abatement with a minimum use of diluent nitrogen gas without sacrificing safety.

### BRIEF DESCRIPTION OF DRAWINGS

FIG. 1 is a diagram showing an overview of an apparatus for exhaust gas abatement under reduced pressure according to an embodiment of the present invention.

FIG. 2 is a partial cross-sectional front view showing an example of a reaction tube of the apparatus for exhaust gas abatement under reduced pressure according to the present invention.

FIG. 3 is a diagram illustrating a main part of the reaction tube of the apparatus for exhaust gas abatement under reduced pressure according to the present invention.

### DESCRIPTION OF EMBODIMENTS

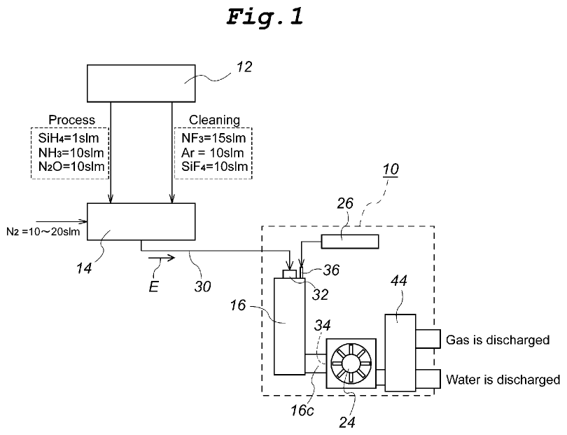

Hereinafter, an embodiment of the present invention will be described with reference to FIG. 1 to FIG. 3.

FIG. 1 is a diagram showing an overview of an apparatus 10 for exhaust gas abatement under reduced pressure according to an embodiment of the present invention. As shown in FIG. 1, the apparatus 10 for exhaust gas abatement under reduced pressure according to this embodiment is an apparatus for abatement of an exhaust gas E supplied from an exhaust gas source 12 such as a CVD apparatus through a vacuum pump 14, and generally includes a reaction tube 16 having a reaction chamber 18 and a combustion chamber 20 and a downstream vacuum pump 24.

Here, the embodiment of FIG. 1 shows a silicon oxynitride film CVD apparatus as an example of the exhaust gas source 12. In a typical silicon oxynitride film CVD apparatus, SiH₄/NH₃/N₂O=1 slm/10 slm/10 slm is used as a process gas, and NF₃/Ar=15 slm/10 slm is used as a cleaning gas. It is presumed that SiF₄ as a product of the cleaning reaction is emitted at about 10 slm. A mixture of these spent gases is supplied as the exhaust gas E to the apparatus 10 for abatement under reduced pressure through the vacuum pump 14. It should be noted that in a semiconductor device manufacturing process such as a CVD process for forming silicon oxynitride films, a dry pump is mainly used as the vacuum pump 14. Therefore, N₂ (nitrogen gas) supplied to this vacuum pump 14 is purging N₂ supplied to seal the shaft of the vacuum pump 14.

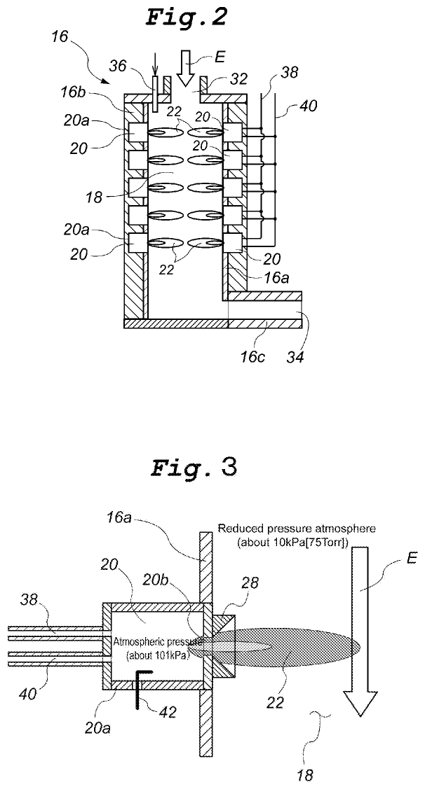

The reaction tube 16 is formed of a corrosion-resistant metallic material such as Hastelloy (registered trademark), and has an approximately cylindrical casing 16a that is placed with its axis vertical (see FIG. 2). The inner space of the casing 16a serves as a reaction chamber 18 for decomposing the exhaust gas E, and the top surface of the casing 16a is provided with an exhaust gas inlet 32 communicating with the outlet of the vacuum pump 14 through a pipe 30. On the other hand, the inlet end of a horizontally extending duct 16c is connected to the lower part of the casing 16a, and the outlet end of the duct 16c is provided with an exhaust gas outlet 34 connected directly to the inlet of a downstream vacuum pump 24.

A nozzle 36 for introducing a decomposition/reaction agent such as water supplied from a decomposition/reaction agent supply unit 26 into the reaction chamber 18 in the casing 16a is optionally provided in the vicinity of the exhaust gas inlet 32 of the casing 16a.

Furthermore, a plurality of combustion chambers 20 arranged in rows and columns in the circumferential and longitudinal directions are provided in the lateral circumferential wall (inner circumferential wall) of the casing 16a.

It should be noted that a reference sign 16b in FIG. 2 indicates a heat insulating material covering the outer circumference of the casing 16a.

The combustion chambers 20 are each formed inside a chamber 20a formed of a heat-resistant and corrosion-resistant metallic material such as Hastelloy (registered trademark). The interior of the chamber 20a is maintained at approximately atmospheric pressure, and a fuel is burned in the chamber 20a, i.e., in the combustion chamber 20, to produce a flame 22 and the flame 22 thus produced is emitted into the reaction chamber 18.

As shown in FIG. 3, one face of the chamber 20a that forms the combustion chamber 20 is formed in a shape that conforms to the wall of the casing 16a and integrally provided thereon to form a part of the wall of the casing 16a. The face of the chamber 20a integrally provided on the wall of the casing 16a is provided with a flame outlet 20b, and a flame stabilizing nozzle 28 having a shape like a Laval nozzle, for example, is optionally attached to that flame outlet 20b. To the chamber 20a, a fuel supply pipe 38 for supplying a combustible fuel gas such as a hydrocarbon-based gas into the combustion chamber 20 in the chamber 20a and an oxidant gas supply pipe 40 for supplying an oxidation gas such as oxygen or air thereinto are connected, and the chamber 20a is further provided with an ignitor 42 for burning these gases to produce the flames 22.

The downstream vacuum pump 24 is a pump for reducing the pressure in the region located downstream of the outlet of the vacuum pump 14 and including the reaction chamber 18 of the reaction tube 16 to a predetermined degree of vacuum and drawing the exhaust gas E that has undergone abatement treatment in the reaction chamber 18 to discharge it. In the present embodiment, a water-sealed pump is used as the downstream vacuum pump 24. Therefore, at the outlet of the downstream vacuum pump 24, a separator 44 such as a gas-liquid separator coalescer is optionally provided to separate the treated exhaust gas E and the seal water in their mixture discharged from the downstream vacuum pump 24 (see FIG. 1).

Here, the reduced pressure created by the downstream vacuum pump 24 for the exhaust gas flow region located downstream of the outlet of the vacuum pump 14 and including the reaction chamber 18 is preferably in a range of 1 Torr or more and 400 Torr or less, and more preferably in a range of 100±50 Torr. When the reduced pressure is lower than 1 Torr, an expensive and elaborate system is needed to achieve a high vacuum environment. In contrast, when the reduced pressure is higher than 400 Torr, which is not very different from the atmospheric pressure, the exhaust gas E must be diluted with a large amount of nitrogen gas, which is comparable to the amount of nitrogen gas required to dilute the exhaust gas E under atmospheric pressure.

It is needless to say that the apparatus 10 for exhaust gas abatement under reduced pressure according to the present embodiment includes various types of detectors, controllers, and power supplies that are necessary to produce the flames 22 in the combustion chambers 20 and operate the downstream vacuum pump 24 and others, although not shown in the figures.

Next, a method for exhaust gas E abatement under reduced pressure using the apparatus 10 for exhaust gas abatement under reduced pressure configured as described above will be described.

The exhaust gas E discharged from the exhaust gas source 12 is delivered to the reaction tube 16 through the vacuum pump 14. When the downstream vacuum pump 24 is operated, the exhaust gas E is introduced into the reaction chamber 18 under a predetermined reduced pressure, where the exhaust gas E is decomposed by the combustion heat of the flames 22 emitted from the combustion chambers 20.

According to the method for exhaust gas abatement under reduced pressure of the present embodiment, the exhaust gas E is decomposed by the combustion heat of the flames 22 under the reduced pressure, and therefore there is no need to use diluent nitrogen gas or the use of the nitrogen gas can be reduced to a minimum. Since there is no need to dilute with diluent nitrogen gas or the use of the nitrogen gas can be reduced to a minimum, almost all combustion heat of the flames 22 can be used directly for decomposition/reaction of the exhaust gas E. A combination of these two advantageous effects allow the exhaust gas E abatement apparatus to be configured very compactly.

In addition, since the region located downstream of the outlet of the exhaust gas source and including the abatement treatment unit is under the reduced pressure, even if the exhaust gas E contains toxic substances to humans, there is no risk that the exhaust gas E leaks from the system before being decomposed by the combustion heat of the flames 22.

The following modifications may be made to the embodiment described above.

In the above embodiment, a plurality of combustion chambers 20 arranged in rows and columns in the circumferential and longitudinal directions are provided in the lateral circumferential wall (inner circumferential wall) of the casing 16a. However, only one combustion chamber 20 may be provided in the reaction tube 16 as long as the flame 22 emitted from the one combustion chamber 20 can thermally decompose the exhaust gas E sufficiently. The positions of the combustion chambers 20 in the casing 16a are also not limited to the above embodiment.

In the above embodiment, water is given as an example of the decomposition/reaction agent supplied from the decomposition/reaction agent supply unit 26. However, for example, when the exhaust gas E contains a large amount of perfluorinated compounds (PFCs) such as NF₃ and thus a large amount of HF is produced as a decomposition/reaction product, it is preferable to add an alkaline aqueous solution such as a KOH aqueous solution or a NaOH aqueous solution as a neutralizer (decomposition/reaction agent). For oxidation treatment, air or oxygen may be added, or a hydrocarbon-based gas such as reducing H₂ or CH₄ may be added.

In the above embodiment, a water-sealed pump is used as the downstream vacuum pump 24. However, a dry pump or the like may be used instead of this water-sealed pump, for example, when there is no need to wash decomposition products with water after the exhaust gas E abatement treatment.

In the above embodiment, the vacuum pump 14 and the exhaust gas inlet 32 of the reaction tube 16 are connected by the pipe 30. However, the outlet of the vacuum pump 14 and the exhaust gas inlet 32 may be connected directly to each other. Furthermore, in the above embodiment, the exhaust gas outlet 34 of the reaction tube 16 and the inlet of the downstream vacuum pump 24 are connected directly to each other. However, the exhaust gas outlet 34 of the reaction tube 16 and the downstream vacuum pump 24 may be connected by a pipe.

It will be understood that various modifications may be made to the above embodiment within the scope of knowledge of those skilled in the art.

### REFERENCE SIGNS LIST

10: Apparatus for exhaust gas abatement under reduced pressure

12: Exhaust gas source

14: Vacuum pump

16: Reaction tube

18: Reaction chamber

20: Combustion chamber

20b: Flame outlet

22: Flame

24: Downstream vacuum pump

26: Decomposition/reaction agent supply unit

28: Flame stabilizing nozzle

E: Exhaust gas

1. A method for exhaust gas abatement under reduced pressure, comprising
decomposing an exhaust gas that is supplied from an exhaust gas source through a vacuum pump by combustion heat of a flame under a reduced pressure.

2. The method for exhaust gas abatement under reduced pressure according to claim 1, wherein the reduced pressure is in a range of 1 Torr or more and 400 Torr or less.

3. An apparatus for exhaust gas abatement under reduced pressure, comprising:
a reaction chamber in which an exhaust gas supplied from an exhaust gas source through a vacuum pump is decomposed by combustion heat of a flame;
a combustion chamber that is maintained at approximately atmospheric pressure and from which the flame is emitted into the reaction chamber; and
a downstream vacuum pump that reduces a pressure in a region located downstream of an outlet of the vacuum pump and including the reaction chamber.

4. The apparatus for exhaust gas abatement under reduced pressure according to claim 3, further comprising a decomposition/reaction agent supply unit that supplies at least one selected from the group consisting of water, air, O₂, H₂, and hydrocarbon gases, as a decomposition/reaction agent, to the reaction chamber.

5. The apparatus for exhaust gas abatement under reduced pressure according to claim 3, further comprising a flame stabilizing nozzle that is provided at a flame outlet of the combustion chamber to stabilize the flame.
